(19) United States
(12) Patent Application Publication
(10) Pub. No.: US 2009/0072320 A1
(43) Pub. Date: Mar. 19, 2009

(54) Asymmetrical layout for complementary metal-oxide-semiconductor integrated circuit to reduce power consumption

(76) Inventor: Joyce Kim, Berkeley, CA (US)

Correspondence Address: William C. Milks, III;RUSSO & HALE LLP, 401 Forence Street, Palo Alto, CA, 94301, US

(21) Appl. No.: 11/901,608

(22) Filed: Sep. 17, 2007

(51) Int. Cl. H01L 27/092; G06F 17/50

(52) U.S. Cl. 257/369; 716/8; 257/E27.062

(57) ABSTRACT

A Complementary Metal-Oxide-Semiconductor (CMOS) integrated circuit design layout incorporating an asymmetrical polysilicon gate and diffusion is disclosed. The resulting asymmetrical CMOS integrated circuit exhibits reduced current flow during operation to thereby decrease power consumption.

### BACKGROUND OF THE INVENTION

1. Field of the Invention

The present invention relates generally to the design of integrated circuits for fabrication by a semiconductor manufacturing process and, more particularly, to an asymmetrical layout for an integrated circuit having reduced power consumption during operation. Specifically, one embodiment of the present invention provides a layout for a Complementary Metal-Oxide-Semiconductor (CMOS) integrated circuit design incorporating an asymmetrical polysilicon gate and diffusion, which exhibits reduced current flow during operation to thereby decrease power consumption, and a method for layout.

2. Description of the Prior Art

The semiconductor manufacturing industry is continually evolving semiconductor device designs and fabrication processes and developing new processes to produce smaller and smaller geometries of the designs being manufactured, because smaller semiconductor devices typically consume less power, generate less heat, and operate at higher speeds than larger devices. Currently, a single integrated circuit chip may contain over one billion patterns.

Improving the design to decrease power consumption is a critical problem in the semiconductor manufacturing industry and has a direct correlation to the amount of heat that is generated during operation. Reduced power consumption results in lower generation of heat. Additionally, lower power consumption yields longer battery life in circumstances when the integrated circuit is incorporated into a battery-operated system or operated in a battery-powered mode.

The design of the integrated circuit is typically rendered as shapes comprising a layout on a mask whose image is transferred by a photolithographic process to produce the desired image on a wafer. An optical system is used to print the image of the mask onto the wafer.

CMOS is a major class of integrated circuits. CMOS technology is used in chips such as microprocessors, microcontrollers, static random access memory (SRAM), and other digital logic circuits. CMOS technology is also used for a wide variety of analog circuits such as image sensors, data converters, and highly integrated transceivers for many types of communication.

Two important characteristics of CMOS devices are high noise immunity and low static power supply drain. Significant power is only drawn when their transistors are switching between on and off states; consequently, CMOS devices do not produce as much heat as other forms of logic such as transistor-transistor-logic (TTL). In addition, the simplicity and comparatively low power dissipation of CMOS circuits have allowed integration densities not possible on the basis of bipolar junction transistors. CMOS also allows a high density of logic functions on a chip.

The triple compound “metal-oxide-semiconductor” refers to the conventional physical structure of field-effect transistors, having a metal gate electrode placed on top of an oxide insulator, which in turn is on top of a semiconductor material. Instead of metal, current gate electrodes (including those up to the 65-nanometer technology node) are typically made from a different material, polycrystalline silicon (“polysilicon”), which can better tolerate the high temperatures used to anneal the semiconductor such as silicon after ion implantation. This means that the gate can be put on early in the process and then used directly as an implant mask producing a self-aligned gate (gates that are not self-aligned require overlap which increases device size and stray capacitance). Metal gates have made a comeback with the advent of high-k dielectric materials in the CMOS transistor as announced by IBM and Intel for the 45-nanometer node and beyond. See, http://www.intel.com/technology/silicon/45nm_technology.htm.

CMOS is also sometimes explained as complementary-symmetry metal-oxide-semiconductor. The words “complementary-symmetry” refer to the fact that the typical digital design style with CMOS uses complementary and symmetrical pairs of P-type and N-type metal-oxide-semiconductor field effect transistors (MOSFETs) for logic functions.

In CMOS logic gates a collection of N-type MOSFETs is arranged in a pull-down network between the output and the lower-voltage power supply rail (often named V_{SS} or quite often ground). CMOS logic gates have a collection of P-type MOSFETs in a pull-up network between the output and the higher-voltage power supply rail (often named V_{DD}). The terminology “pull-up” and “pull-down” refer to the concept that the output node, which happens to be where the pull-up and pull-down networks intersect, exhibit some internal capacitance that is charged or discharged, respectively, through pathways formed by the P/NMOS networks for various inputs. This capacitance is charged when there is a direct path from V_{DD} to the output, and discharged when there is a direct path from the output to V_{SS} or ground. Note that a digital CMOS circuit cannot (ideally) be in a pull-up and pull-down phase at the same time, or else both the P/NMOS networks will fight to keep the voltage on the capacitance either V_{DD} or ground. The P-type transistor network is complementary to the N-type transistor network, so that when the N-type is off, the P-type is on, and vice-versa.

P-type MOSFETs are complementary to N-type because they turn on when their gate voltage goes sufficiently below their source voltage, and because they can pull the drain all the way to V_{DD}. Thus, if both a P-type and N-type transistor have their gates connected to the same input, the P-type MOSFET will be on when the N-type MOSFET is off, and vice-versa.

FIG. 1 illustrates a design for a conventional CMOS circuit, namely, an inverter circuit, also called a NOT gate. The circuit comprises a PMOS field effect transistor (top half of the diagram) and an NMOS field effect transistor (bottom half) connected between voltage rails. If the input (IN) is a logic high, then the N-type transistor will conduct, the P-type transistor will not conduct, and a conductive path will be established between the output (OUT) and V_{SS} or ground, bringing the output low. If the input is low, the N-type transistor will not conduct, the P-type transistor will conduct, and a conductive path will be established between the output and V_{DD}, bringing the output high. Thus, if the input is a logic low it is converted to a logic high. If the input is a logic high it is converted to a logic low.

FIG. 2 shows a physical layout of an inverter circuit (based on the CMOS logic example shown in FIG. 1) and illustrates a NOT logic device drawn as a physical representation as it would be manufactured. The physical layout perspective is an elevational view of a stack of layers. The circuit is constructed on a P-type substrate. The polysilicon, diffusion, and N-well are referred to as “base layers” and are actually inserted into trenches of the P-type substrate. The contacts penetrate an insulating layer between the base layers and the first layer of metal making a connection.

The input to the inverter is in polysilicon. The CMOS transistors (devices) are formed by the intersection of the polysilicon and diffusion: N diffusion for the N device; P diffusion for the P device, respectively. The output is connected to in metal. Connections between metal and polysilicon or diffusion are made through metal contacts. The physical layout example matches the NOT logic circuit described in conjunction with FIG. 1.

As another example, shown in FIG. 3 is a circuit diagram of a NAND gate in CMOS logic. If both of the A and B inputs are high, then both the N-type transistors (bottom half of the diagram) will conduct, neither of the P-type transistors (top half) will conduct, and a conductive path will be established between the output (Out) and V_{SS}, bringing the output low. If either of the A or B inputs is low, one of the N-type transistors will not conduct, one of the P-type transistors will conduct, and a conductive path will be established between the output and VDD, bringing the output high.

The physical layout of a NAND circuit (based on the CMOS logic example shown in FIG. 3) is shown in FIG. 4 and illustrates a NAND logic device drawn as a physical representation as it would be manufactured. The physical layout perspective is an elevational view of a stack of layers. The circuit is constructed on a P-type substrate. The polysilicon, diffusion, and N-well are base layers and are actually inserted into trenches of the P-type substrate. The contacts penetrate an insulating layer between the base layers and the first layer of metal 1 making a connection.

The inputs to the NAND circuit are in polysilicon 3. The CMOS transistors (devices) are formed by the intersection of the polysilicon and diffusion: N diffusion 5 for the N device; P diffusion 7 for the P device , respectively. The output is connected together in metal 1. Connections between metal and polysilicon or diffusion are made through contacts 9. The physical layout example matches the NAND logic circuit described in conjunction with FIG. 3.

Additionally, the N device is manufactured on a P-type substrate. The P device is manufactured in an N-type well (N-well) illustrated in dashed lines. A P-type substrate “tap” is connected to V_{SS} and an N-type N-well tap is connected to V_{DD} to prevent latchup.

CMOS circuits dissipate power by charging and discharging the various load capacitances (mostly gate and wire capacitances, but also drain and some source capacitances) whenever they are switched. The charge moved is the capacitance multiplied by the voltage change. Multiplying by the switching frequency gives the current used, and multiplying by voltage again yields the characteristic switching power dissipated by a CMOS device: P=CV²f.

Both NMOS and PMOS field effect transistors have a threshold gate-to-source voltage, below which the current through the device drops exponentially. Historically, CMOS designs operated at supply voltages much larger than their threshold voltages (V_{DD} might have been 5 V, and Vₜₕ for both NMOS and PMOS might have been 700 mV). But as supply voltages have come down to conserve power, the V_{DD} to V_{SS} short circuit is avoided.

However, to speed up the designs, manufacturers have switched to gate materials which lead to lower voltage thresholds, and a modern NMOS transistor with a Vₜₕ of 200 mV has a significant subthreshold leakage current. Designs (e., desktop processors) which try to optimize their fabrication processes for minimum power dissipation during operation have been lowering Vₜₕ so that leakage power begins to approximate switching power. As a result, these devices dissipate considerable power even when not switching. Leakage power reduction using new material and system design is critical to sustaining scaling of CMOS. The industry is contemplating the introduction of high-k dielectrics to combat the increasing gate leakage current by replacing the silicon dioxide constituting the conventional gate dielectrics with materials having a higher dielectric constant.

A different form of power consumption has become more prevalent as wires on chip have become narrower and the long wires have become more resistive. CMOS gates at the end of those resistive wires see slow input transistions. During the middle of these transitions, both the NMOS and PMOS networks are partially conductive, and short circuit current flows directly from V_{DD} to V_{SS}. The power thus used is called crowbar power. Careful design which avoids weakly driven long skinny wires has ameliorated this effect to some extent, and crowbar power is typically substantially smaller than switching power. Nevertheless, unwanted power consumption persists.

In summary, CMOS circuits exhibit power losses during operation. Thus, it would be desirable to provide a CMOS integrated circuit design layout and method for layout which overcome the above limitations and disadvantages of conventional CMOS integrated circuit design layouts and layout techniques, for example, to reduce power consumption during operation of CMOS integrated circuits. It would also be desirable to provide a design layout and method for layout that facilitate fabrication of CMOS integrated circuits while at the same time leading to reduced power consumption. It is to these ends that the present invention is directed. The various embodiments of the present invention provide many advantages over conventional CMOS integrated circuit design layouts and layout techniques.

### SUMMARY OF THE INVENTION

The various embodiments of the asymmetrical CMOS integrated circuit design layout and method for layout in accordance with the present invention provide many advantages over conventional CMOS design layouts and layout techniques, which make the asymmetrical CMOS integrated circuit design layout and method for layout in accordance with the embodiments of the present invention more useful to semiconductor manufacturers. For example, various embodiments of the asymmetrical CMOS integrated circuit design layout and method for layout in accordance with the present invention reduce power consumption by minimizing short circuit current. One embodiment of the present invention incorporates an asymmetrical polysilicon gate and diffusion, whose operation exhibits reduced current flow during operation to thereby decrease power consumption. That is, the various embodiments of the present invention provide a low-power design layout using an asymmetrical polysilicon gate and diffusion in a CMOS integrated circuit design to thereby minimize a short circuit condition, thus saving on associated unwanted power consumption. Accordingly, the various embodiments of the present invention provide a design layout and methodology that produce CMOS integrated circuits which have enhanced efficiency.

The asymmetrical CMOS integrated circuit design layout and method for layout in accordance with the various embodiments of the present invention can be applied to CMOS logic, for example, inverters and NAND gates. The principles of the present invention also apply to other CMOS logic devices.

The foregoing and other objects, features, and advantages of the present invention will become more readily apparent from the following detailed description of various embodiments, which proceeds with reference to the accompanying drawing.

### BRIEF DESCRIPTION OF THE DRAWING

The various embodiments of the present invention will be described in conjunction with the accompanying figures of the drawing to facilitate an understanding of the present invention. In the figures, like reference numerals refer to like elements. In the drawing:

FIG. 1 is a schematic circuit diagram of a conventional CMOS inverter circuit;

FIG. 2 illustrates a CMOS integrated circuit design layout for the inverter circuit shown in FIG. 1;

FIG. 3 is a schematic circuit diagram of a conventional CMOS NAND gate;

FIG. 4 illustrates a CMOS integrated circuit design layout for the NAND gate shown in FIG. 3;

FIG. 5 illustrates an example of an asymmetrical CMOS integrated circuit design layout for an inverter circuit in accordance with one embodiment of the present invention;

FIG. 6 is a table showing the results of SPICE simulations for asymmetrical polysilicon gate and diffusion layouts for an inverter circuit and a NAND gate;

FIG. 7 is a graph of average current for a CMOS inverter circuit having the design layout shown in FIG. 5 as a function of the length of the polysilicon gate for various diffusion widths;

FIG. 8 is a graph of average current for a CMOS NAND gate as a function of the length of the polysilicon gate for various diffusion widths; and

FIG. 9 is a flow diagram illustrating an embodiment of the method for layout in accordance with one embodiment of the present invention.

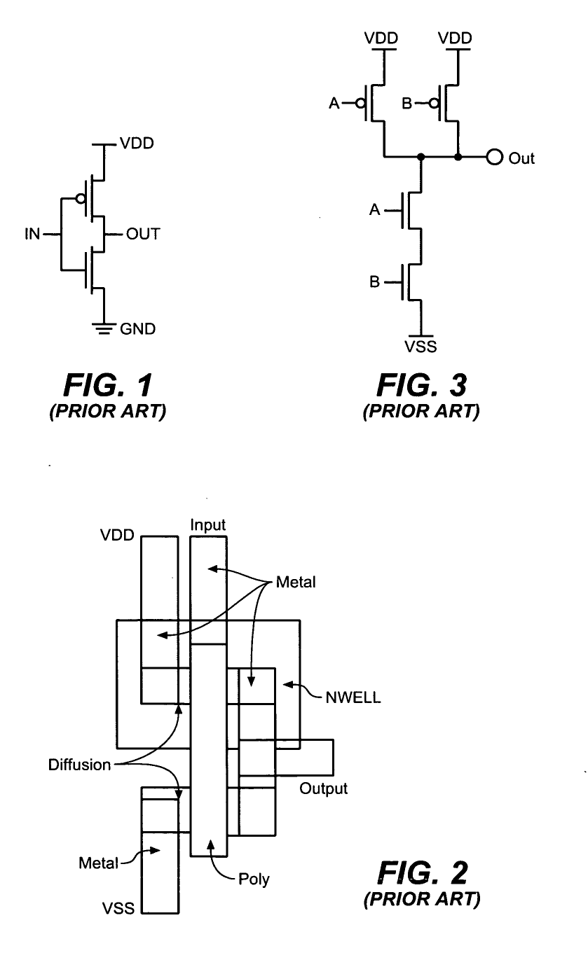

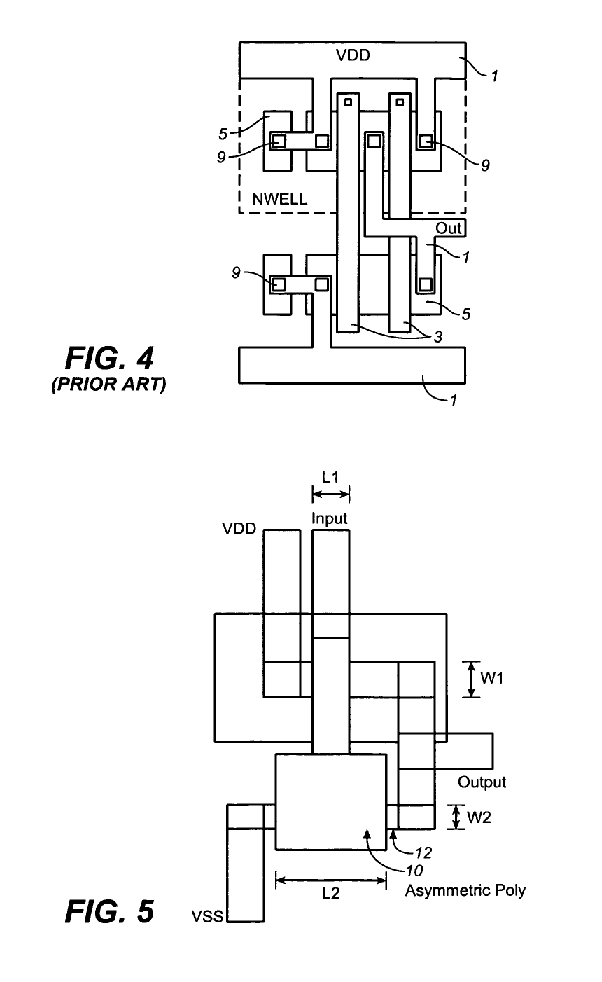

### DETAILED DESCRIPTION OF THE PREFERRED EMBODIMENTS

The present invention is particularly applicable to a design layout for producing a CMOS integrated circuit, and it is in this context that the various embodiments of the present invention will be described. It will be appreciated that while the asymmetrical CMOS integrated circuit design layout and method for layout in accordance with the one embodiment of the present invention will be described for an inverter circuit, the asymmetrical CMOS integrated circuit design layout and method for layout have greater utility, since they may be employed for producing other CMOS integrated circuits not described in detail herein. The underlying principle of various embodiments of the present invention is to provide an asymmetrical polysilicon gate and diffusion in the CMOS integrated circuit design layout.

FIG. 5 illustrates an example of an asymmetrical CMOS integrated circuit design layout for an inverter circuit in accordance with one embodiment of the present invention. The asymmetrical CMOS integrated circuit design layout incorporates an asymmetrical polysilicon gate 10 and diffusion 12 for the N-type transistor. The polysilicon gate 10 has a length L2, and the diffusion has a width W2 compared with the symmetrical length L1 and width W1. The asymmetrical polysilicon gate 10 and diffusion 12 will cause the P-type and N-type transistors to switch at different times, thereby decreasing short circuit current and reducing power consumption. Advantageously, the asymmetrical polysilicon gate 10 and diffusion 12 provide effective power savings.

Operation of conventional CMOS logic circuits typically includes a transition current that is a characteristic of CMOS behavior, during which the short circuit current flows when the PINMOS devices turn on at the same time. This transition moment cannot be avoided, due to the characteristics of typical CMOS operation. The resulting wasted power usage can reach 30% of the total power usage.

The asymmetrical CMOS integrated circuit design layout using an symmetrical polysilicon gate 10 and diffusion 12 as shown in FIG. 5 for an inverter circuit saves 30-40% of total power usage compared with a conventional CMOS integrated inverter circuit design layout. Therefore, the asymmetrical CMOS integrated circuit design layout in accordance with the various embodiments of the present invention can reduce the total power usage by 30-40% by differentiating the switching turn on time of the P and NMOS devices.

The turn on time typically is dependent on the resistance of the diffusion layer, as well as the capacitance of the polysilicon gate layer. Therefore, the dimensions of the asymmetrical polysilicon gate and diffusion can both be modified to preferably produce a different switching moment by differentiating the resistance and capacitance of the P and NMOS devices. As a result, different switching times of the P/NMOS devices saves considerable energy and can do so without wasting area on the wafer.

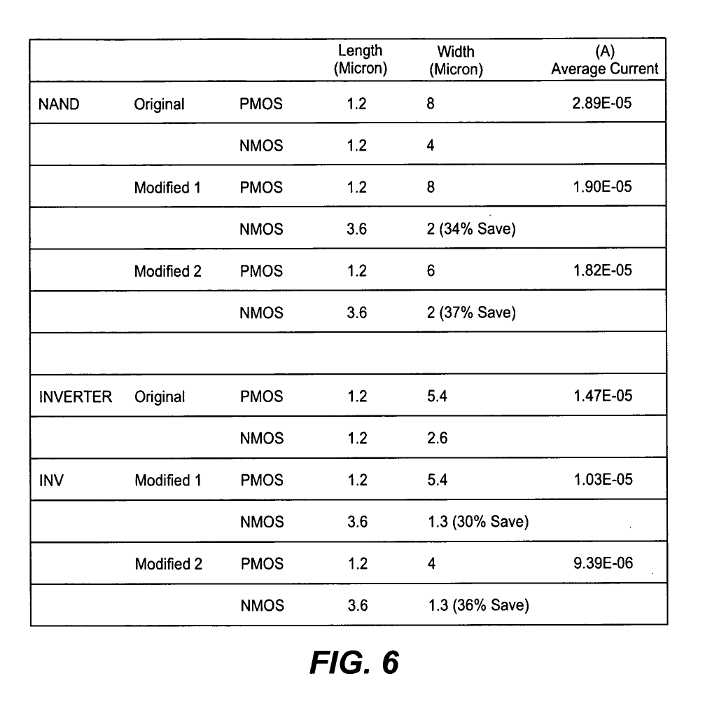

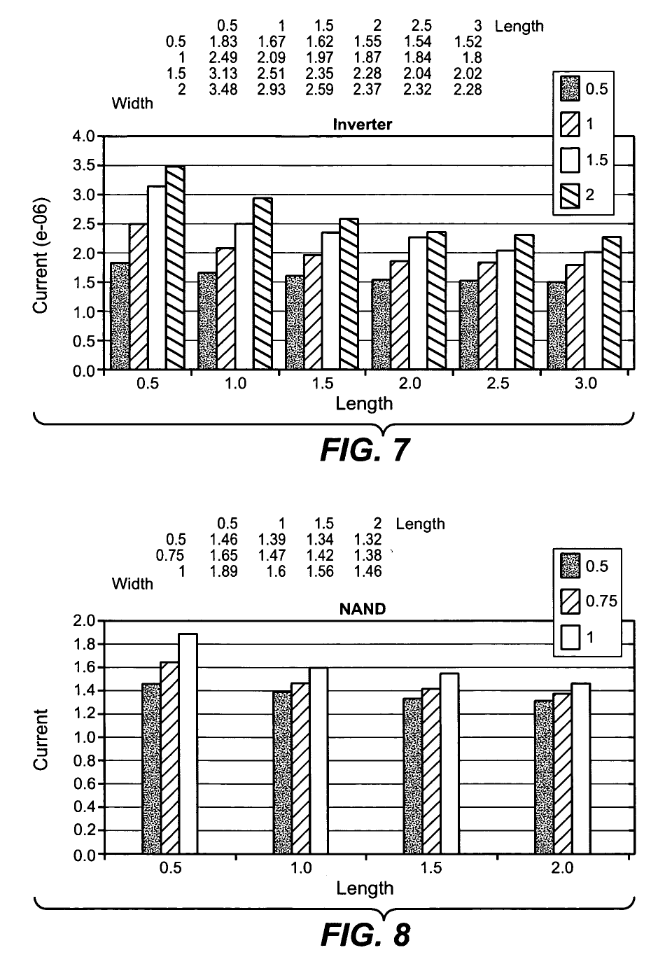

Results shown in FIG. 6 from SPICE simulations for design layouts having asymmetrical polysilicon gate and diffusion for an inverter circuit and a NAND gate demonstrate that 56% of the power usage can be saved. The drain area expansion of the PMOS and NMOS may also contribute to the power savings. This is more than 30% of total power usage. This is because 44% of the original power is enough to charge the CMOS devices if the transition current is well-controlled. The SPICE results appearing in FIG. 6 and the graphs illustrated in FIGS. 7 and 8 demonstrate that the design layout having an asymmetrical polysilicon gate and diffusion can save a large amount of power.

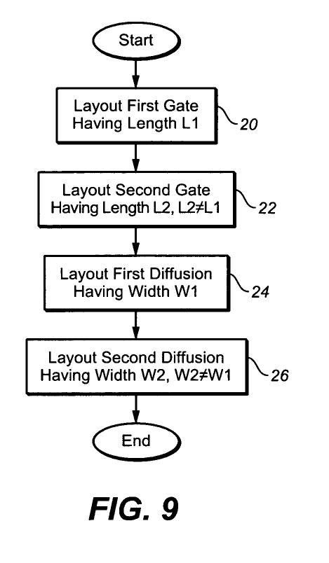

FIG. 9 is a flow diagram illustrating an embodiment of the method for layout in accordance with one embodiment of the present invention. As shown in FIG. 9, layout for a CMOS integrated circuit design includes providing a first gate having a first length L1, as indicated by a step 20. Layout also includes providing a second gate having a second length L2, as indicated by a step 22. Layout further includes providing a first diffusion having a first width W1, as indicated by a step 24. Layout additionally includes providing a second diffusion having a second width W2, as indicated by a step 26. In accordance with one embodiment of the method for layout of the present invention, at least L1 and L2 are different or W1 and W2 are different, thereby producing an asymmetrical CMOS integrated circuit design layout. In accordance with another embodiment of the method for layout of the present invention, both L1 and L2 are different and W1 and W2 are different, thereby producing an asymmetrical CMOS integrated circuit design layout.

While the foregoing description has been with reference to a particular embodiment of the present invention, it will be appreciated by those skilled in the art that changes may be made without departing from the principles and spirit of the invention. Generally speaking, the CMOS integrated circuit design layout and method for layout in accordance with the various embodiments of the present invention apply to any CMOS logic device. The application of commercial usage is for any CMOS device, which is currently the major usage in the semiconductor industry. Accordingly, the scope of the present invention can only be ascertained with reference to the appended claims.

What is claimed is:

1. An asymmetrical Complementary Metal-Oxide-Semiconductor (CMOS) integrated circuit design layout, comprising:
a first gate having a first length;
a second gate having a second length;
a first diffusion having a first width; and
a second diffusion having a second width;
wherein the first length and second length are different or the first width and second width are different.

2. The layout of claim 1 wherein both the first length and second length are different and the first width and second width are different.

3. A method for layout for a Complementary Metal-Oxide-Semiconductor (CMOS) integrated circuit design, comprising the steps of:
providing a first gate having a first length;
providing a second gate having a second length;
providing a first diffusion having a first width; and
providing a second diffusion having a second width;
wherein the first length and second length are different or the first width and second width are different;
thereby producing an asymmetrical CMOS integrated circuit design layout.

4. The method of claim 3 wherein both the first length and second length are different and the first width and second width are different.
